(19) United States
(12) Patent Application Publication
(10) Pub. No.: US 2005/0003617 A1
(43) Pub. Date: Jan. 6, 2005

(54) Template padding method for padding edges of holes on semiconductor masks

(75) Inventors: Shun-Li Lin, Hsinchu (TW); Chen-Fu Chien, Hsinchu (TW); Jing-Feng Deng, Taipei Hsien (TW)

Correspondence Address: John G. Flaim c/o;BAKER & McKENZIE, 2300 Trammell Crow Center, 2001 Ross Avenue, Dallas, TX, 75201, US

(73) Assignee: Macronix International Co., Ltd.

(21) Appl. No.: 10/613,817

(22) Filed: Jul. 1, 2003

(51) Int. Cl. H01L 21/8234

(52) U.S. Cl. 438/275

(57) ABSTRACT

A template padding method for padding edges of at least one hole on a semiconductor mask. The exposure and padding process is modulized. A padding database is developed based on the feature size and the pattern to be exposed. In the method of the present invention, the environment to be exposed is found firstly, and specific exposure module is then searched out. The padding result of the module is pre-found and stored in a database by diffraction operation, such as OPC method. Padding of a hole on a mask about a cell of a wafer can be performed directly by using a value stored. The complicated calculation can be greatly reduced. The method is adjustable according to the feature size of the product and the exposing pattern. The method can be used to random-distribution of holes on a mask surface, so as to determine a padding area effectively.

### FIELD OF THE INVENTION

The present invention relates to a semiconductor manufacturing process, and particularly to a template padding method for padding edges of at least one hole on a semiconductor mask.

### BACKGROUND OF THE INVENTION

In general, a mask is placed at the upper section, and a selective contact layer is placed below the mask during exposure. The selective contact layer is, for example, a programmable layer in forming ROM (Read Only Memory). A wafer is placed below the contact layer.

In lighting process (for example, photolithography process), the pattern of the mask must be firstly developed on the contact layer and the doping process is used to dope impurity of the channel. In general, the pattern is distributed in an area containing a great amount of cells. In the mask, the positions with respect to the channels are opened. The pattern on the mask is projected to the contact layer by photolithography process. Since the mask has a plurality of holes thereon, while the photolithography process is performed on the whole region, it is impossible to perform photolithography process to each hole. Thereby, the light is impinged upon a plurality of holes, thereby, inducing diffraction on the hole to be developed. Namely, the pattern on the mask cannot be completely projected to the contact layer, but the pattern is distorted.

In photolithography, exposure energy, such as ultraviolet light, is passed through a mask (or reticle) and onto a target such as a silicon wafer. The reticle typically may contain opaque and transparent regions formed in a predetermined pattern. The exposure energy exposes the reticle pattern on a layer of resist formed on the target. The resist is then developed for removing either the exposed portions of resist for a positive resist or the unexposed portions of resist for a negative resist. This forms a resist mask. A mask typically comprises a transparent plate such as fused silica having opaque (chrome) elements on the plate used to define a pattern. A radiation source illuminates the mask according to well-known methods. The radiation transmitted through the mask and exposure tool projection optics forms a diffraction limited latent image of the mask features on the photoresist. The resist mask can be used in subsequent fabrication processes. In semiconductor manufacturing, such a resist mask can be used in deposition, etching, or ion implantation processes, to form integrated circuits with very small features.

As semiconductor manufacturing advances to ultra-large scale integration (ULSI), the devices on semiconductor wafers shrink to sub-micron dimension and the circuit density increases to several million transistors per die. In order to accomplish this high device packing density, smaller and smaller feature sizes are required. This may include the width and spacing of interconnecting lines and the surface geometry such as corners and edges, of various features.

As the nominal minimum feature sizes continue to decrease, control of the variability of these feature sizes becomes more critical. For example, the sensitivity of given critical dimensions of patterned features to exposure tool and mask manufacturing imperfections as well as resist and thin films process variability is becoming more significant. To continue developing manufacturable processes in light of the limited ability to reduce the variability of exposure tool and mask manufacturing parameters, it is desirable to reduce the sensitivity of critical dimensions of patterned features to above-mentioned parameters.

As feature sizes decrease, semiconductor devices are typically less expensive to manufacture and have higher performance. In order to produce smaller feature sizes, an exposure tool having adequate resolution and depth of focus at least as deep as the thickness of the photoresist layer is desired. For exposure tools that use conventional or oblique illumination, better resolution can be achieved by lowering the wavelength of the exposing radiation or by increasing the numerical aperture of the exposure tool, but the smaller resolution gained by increasing the numerical aperture is typically at the expense of a decrease in the depth of focus for minimally resolved features. This constraint presents a difficult problem in reducing the patterning resolution for a given radiation wavelength.

A reduction projection exposure method that features mass-producibility and excellent resolution has been used widely for forming patterned features. According to this method, the resolution varies in proportion to the exposure wavelength and varies in inverse proportion to the numerical aperture (NA) of the projection optical system. The NA is a measure of a lens' capability to collect diffracted light from a mask and project it onto the wafer. The resolution limit R (nm) in a photolithography technique using a reduction exposure method is described by the following equation:
R=K₁λ/(NA)

where λ is a wavelength (nm) of the exposure light, NA is a numerical aperture of the lens, and K₁ is a constant dependent on the type of the resist.

So far, increases in the resolution limit have been achieved by increasing the numerical aperture, i.e. high NA. This method, however, is approaching its limit due to, a decrease in the depth of focus, difficulty in the design of lenses, and complexity in the lens fabrication technology itself. In recent years, therefore, attention has been given to an approach for shortening the wavelength of the exposure light in order to form finer patterns to support an increase in the integration density of LSIs. For example, a 1-Gbit DRAM requires a 0.2 μm pattern while a 4-Gbit DRAM requires a 0.1 μm pattern. In order to realize these patterns, exposure light having shorter wavelengths must be used.

However, because of increased semiconductor device complexity that results in increased pattern complexity, and increased pattern packing density on the mask, distance between any two opaque areas is decreased. By decreasing the distances between the opaque areas, small apertures are formed which diffract the light that passes through the apertures. The diffracted light results in effects that tend to spread or to bend the light as it passes so that the space between the two opaque areas is not resolved, thus, making diffraction a severe limiting factor for optical photolithography.

A conventional method of dealing with diffraction effects in optical photolithography is achieved by using a phase shift mask, which replaces the previously discussed mask. Generally, with light being thought of as a wave, phase shifting is a change in timing of a shift in waveform of a regular sinusoidal pattern of light waves that propagate through a transparent material.

In semiconductor process, optical proximity correction (OPC) is an important step in the photolithography lithography. In the development and etching processes of semiconductor devices, the diffraction of light will affect the exposure of light and the padding process is thus necessary. The exposing padding method is determined based on the pattern to be exposed. If the critical dimension of a pattern to be imaged is equal to or smaller than the wavelength of the exposing light, the quality of padding method will affect the exposing effect. Currently, the OPC exposing and padding methods are expensive commercial software. These methods are based on complicated optics, geometry and calculates. The operation time is long and not suitable for products with short turn around times.

### SUMMARY OF THE INVENTION

It is therefore a primary objective of the present invention to provide a template padding method for padding edges of at least one hole on a semiconductor mask to solve the above-mentioned problem. In the present invention, the exposure and padding process is modulized. A padding database is developed based on the feature size and the pattern to be exposed. In this method, the environment to be exposed is found firstly, and then specific exposure module is searched out. The OPC padding result of the module is pre-found and stored in a database by diffraction operation, such as OPC method. The padding of a hole on a mask around a cell of a wafer can be achieved directly by using a value stored in the OPC rule. The complicated calculation thus can be greatly reduced.

The method of the present invention is adjustable according to the feature size of the product and the exposing pattern. Since the padding database is built, the environmental cells around the hole on a mask to be padded can be modulized.

In addition, the method of the present invention can be used to random-distribution of holes on a mask surface, so as to determine a padding area effectively. Furthermore, the operation time for auto OPC of the random pattern can be reduced and the precise of OPC is retained.

To achieve the object, the present invention provides a template padding method for padding edges of at least one hole on a semiconductor mask. The mask being provided on a contact layer formed on a wafer for forming elements, light being impinging into the hole to develop an image of the hole on the contact layer, thereby, the wafer being doped to form semiconductor elements, the mask being dividing into a plurality of cells and at least one cell having a hole. The method comprises the steps of determining a zone enclosing the hole on the mask, the zone containing a plurality of cells, selecting a template adjacent one selected edge to be padded, the template containing the hole and parts of cells in the zone, determining the padded length based on a diffraction result of the hole and cells on the template; and padding all edges of the at least one hole.

The present invention further provides a method for determining a padding length of a padded hole in a template. The template contains a cell array and the padded hole and is a sub-set of a zone on a mask enclosing the padded hole. The cell array is formed by a plurality of adjacent banks each containing a predetermined number of cells. The method comprises the steps of determining the geometrical relation of a selected cell to the at least one hole to be padded for a cell having a hole, determining a padding value according to diffraction of the selected cell and the hole, for cells in the template having the same geometrical relation to the padded hole as the first step, the padding value being equal to that acquired from, determining all the padding values for each cell in the template, adding all of the padding values of each cells in the template, and determining a padding length according to the padding values for expanding an edge of the padded hole, wherein the edge of the hole to be expanded is one of edges of the hole nearest to the template.

The various objects and advantages of the present invention will be more readily understood from the following detailed description when read in conjunction with the appended drawings.

### BRIEF DESCRIPTION OF THE DRAWINGS

FIG. 1A shows a block containing a plurality of cells in a semiconductor element.

FIG. 1B shows a detail structure of a transistor containing a source, a drain and a channel, wherein a resistor is completely isolated the source and the drain.

FIG. 1C shows a detail structure of a transistor containing a source, a drain and a channel, wherein a second resistor is too small to isolate the source and drain.

FIG. 2 shows a basic structure in producing a semiconductor element before masking process.

FIG. 3 shows a zone around a hole to be padded and templates of the zone.

FIG. 4 shows a template of a zone containing four cells.

FIG. 5 shows all possible combinations of a template containing four cells.

FIG. 6 shows a template for lateral side padding, wherein each template has six cells above the hole to be padded and each cell has a respective hole.

FIG. 7 shows a template for lateral side padding, wherein each template has six cells above the hole to be padded and only some cells have their respective holes.

FIG. 8 shows a template for lateral side padding, wherein each template has six cells below the hole to be padded and each cell has a respective hole.

FIG. 9 shows a template for lateral side padding, wherein each template has six cells below the hole to be padded and only some cells have their respective holes.

FIG. 10 shows a template for lateral side padding, wherein each template has six cells at the right side of the hole to be padded and each cell has a respective hole.

FIG. 11 shows a template for lateral side padding, wherein each template has six cells at the right side of the hole to be padded and only some cells have their respective holes.

FIG. 12 shows a template for lateral side padding, wherein each template has six cells at the left side of the hole to be padded and each cell has a respective hole.

FIG. 13 shows a template for lateral side padding, wherein each template has six cells at the left side of the hole to be padded and only some cells have their respective holes.

FIG. 14 shows all possible distribution of a hole in a template having four cells.

FIG. 15 shows a template with an L shape located at a corner of a cell to be padded.

FIG. 16 shows a geometric structure of a template containing a cell to be padded.

FIG. 17 shows a digital array of a mask of a ROM code which can be expanded outward through two rows or columns so as to be formed as an array.

FIG. 18 shows that an area considered in lateral side padding and corner padding can be expanded as desired, wherein two cases are considered.

FIGS. 19A and 19B show a pattern of a mask before padding and after padding by the method of the present invention.

FIG. 20 is a partial enlarged view of the pattern at the left upper side of FIG. 19B.

### DETAILED DESCRIPTION OF THE PRESENT INVENTION

In a photolithography process of semiconductor manufacturing, other than critical dimension must be controlled severely, the shape of pattern to be exposed is important. The OPC method thus will affect the process window in the photolithography process.

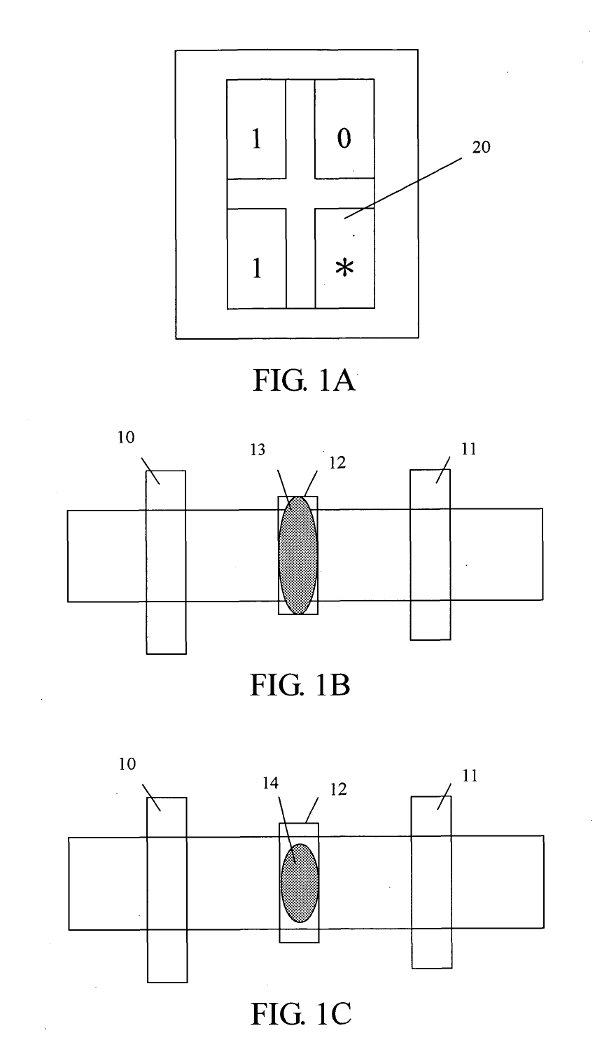

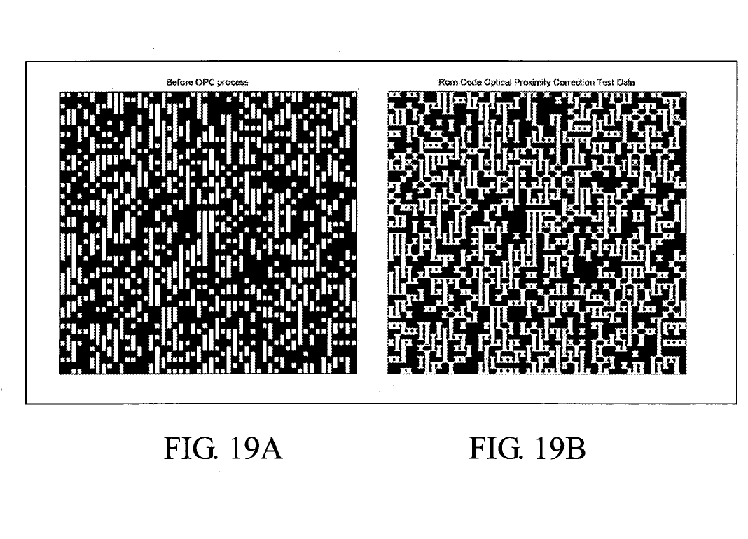

Referring to FIG. 19A, in Mask ROM products, a ROM is formed by a plurality of cells arranged as an array. Referring to FIG. 1A, a small block 20 of FIG. 19A is illustrated with an enlarged view, wherein the block 20 of cells are formed by adjacent transistors with same electrodes (such as sources 10 or drains 11) connected. As can be seen in FIGS. 1B and 1C, a channel 12 is arranged between a source 10 and a drain 11. The value of the cell in the ROM is determined by a resistor 13,14 of the channel 12, i.e. the doping densities of the channel 12. For example, as the density of the channel 12 is dense, the value of the cell is represented by 1. As the density of the channel 12 is low, the value of the cell is represented by 0. However, the doping of the channel 12 makes the channel 12 has a resistor 13,14.

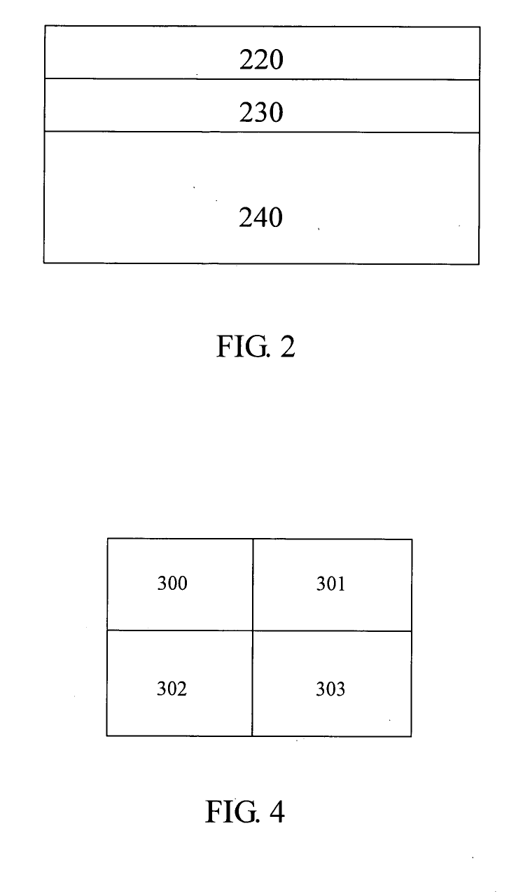

In a photolithography process, a selective contact layer, such as a resist layer, 230 is formed on a wafer 240, as shown in FIG. 2. The selective contact layer 230 is, for example, a programmable layer in forming a ROM. A mask 220 having original pattern is then placed on the contact layer 230. The pattern of the mask 220 must be firstly developed on the contact layer 230 and a doping process is performed to dope impurity of the channel. In general, the pattern is distributed in an area containing a great amount of cells, as shown in FIG. 19A. In the mask 220, the positions with respect to the channels 12 are opened. For example, the channels represented by “1” are closed without any holes, while the channels represented by “0” are opened with hole on the mask. During exposure, light is impinged upon the holes of the mask 220, diffraction occurs on the holes and a distortion occurs to the transferred pattern. Therefore, the pattern on the mask 220 cannot be completely transferred to the contact layer 230.

Referring to FIG. 1B, it is preferred that the channel 12 has a rectangular shape which covers the area between the source 10 and the drain 11 of a transistor. The resistor 13 (doping area of the channel 12) is large enough to isolate the source 10 and the drain 11 such that no current can flow through the channel 12. The value of the cell thus can be clearly identified. Due to the diffraction effect, after being transferred from a mask to a resist layer on a wafer, a right angle corner of the pattern on the mask is often rounded, the line ends would become short, or the line widths increase/decrease. The transferred shape on the contact layer 230 is generally elliptic rather than rectangular, as shown in FIG. 1B. If the elliptic shape of the resistor 14 is too small to isolate the source 10 and the drain 11, as shown in FIG. 1C, the resistor 14 cannot wholly cover the channel 12. Current will flow between the source 10 and the drain 11 and the value of that cell will become vague. If the elliptic shape is prolonged, two sides of long axis of the elliptic shape will intrude into the cell at the next bank. If the distances between banks of cells are enlarged, the density of the whole ROM will be reduced and the number of total cells will be decreased. This is not a preferred result. Therefore, there is an eager demand to make the doping of the channel to be a rectangular shape or an approximate rectangular shape. To this end, the shape of holes on the mask must be modified.

OPC method is used to correct the shape of holes on the mask so that holes formed on the contact layer 230 are rectangular or approximately rectangular. The OPC method pads the edges of the holes on the mask so that the holes on the contact layer 230 are formed as rectangular shape after diffraction.

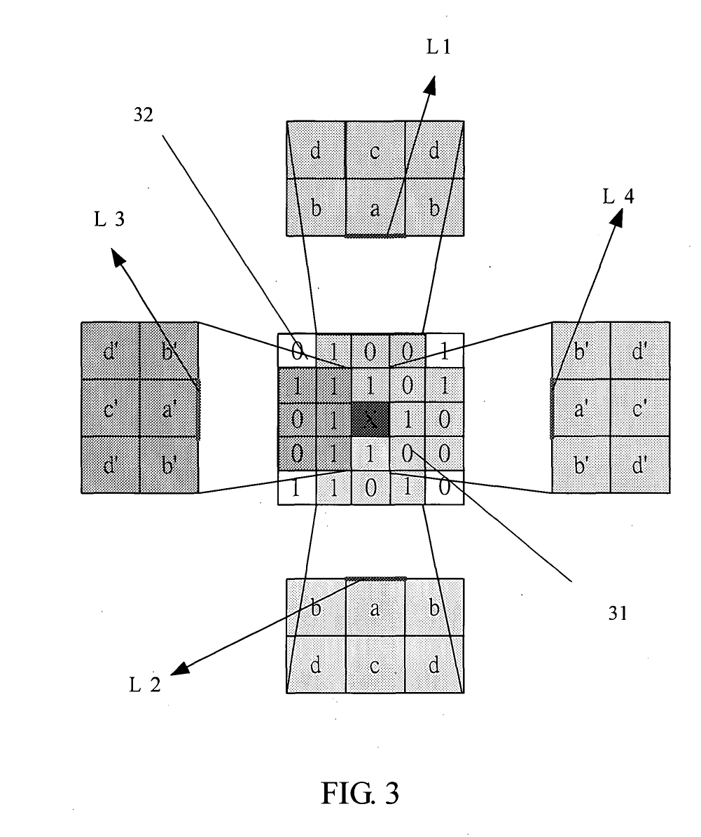

Referring to FIG. 3, 0s represent the cells which have a hole to be developed for further doping the wafer 240 to have a dense impurity so as to present a resistor, and 1s represent the cells which do not have any hole thereon. Alternatively, cells having respective holes thereon can be defined as “1” and cells with no hole thereon can be defined as “0”. Alternatively, cells having holes thereon can be defined as “0” and cells having no hole thereon can be defined as “1”. It will not affect the result of the present invention described in the following.

As shown in FIG. 3, a hole X to be developed is surrounded by a plurality of holes which are randomly arranged around the hole X. Calculating the diffraction of the patterns is very complex and the patterns of the hole distribution are very complicated and irregular. The calculation of OPC method thus is very large. To solve this problem, the conventional OPC is modified. There are two kinds of modified OPC method, one is rule OPC and the other is model OPC.

In rule OPC, many rules are found out to confine the OPC. Each rule is suitable for some specific relations of hole distributions. The calculation in rule OPC is very large and complicated, especially, the number of cells on a mask increase rapidly and greatly. In a compact area, a large amount of holes are distributed thereon. As a result, complexity is far over the calculating capability OPC. Thus a long time is needed in calculation. Since clients often request that products should be produced within a short producing period such as within one week, a long calculation time cannot meet the requirement of market. These problems are also occurred in model OPC.

Therefore, the prior art cannot effectively and rapidly calculate the padding patterns of holes on a mask to meet the requirement of clients.

The method of the present invention will be described hereinafter, which resolves the defect of prior art so as to have a quick calculation time to meet the requirement in the market.

In practical use, for a selected hole to be developed, only finite adjacent holes adjacent to the hole to be developed have effect in the calculation of OPC. In the present invention, as can been seen in FIG. 3, the section around the hole is divided into several rectangular zones with each outer zone enclosing the inner zone and each zone containing one bank of cells. The zones are indicated as a first zone 31, second zone 32, etc.

In the present invention, the OPC method is used, but only the area within a selected zone is considered in the calculation of diffraction. For example, with reference to FIG. 3, when the second zone 32 is selected to be related in calculating of OPC and it is desired to pad the hole X, only the cells at two nearest banks adjacent to the hole X are considered in the OPC calculation.

The selection of zones in calculating OPC is based on the diffraction effect, i.e., the ratio of the size of hole to the length of incident light wave. If the ratio is large, the diffraction effect is large and a larger zone is need. On the other hand, if the ratio is small, the diffraction effect will be non-obvious and a small zone is thus sufficient.

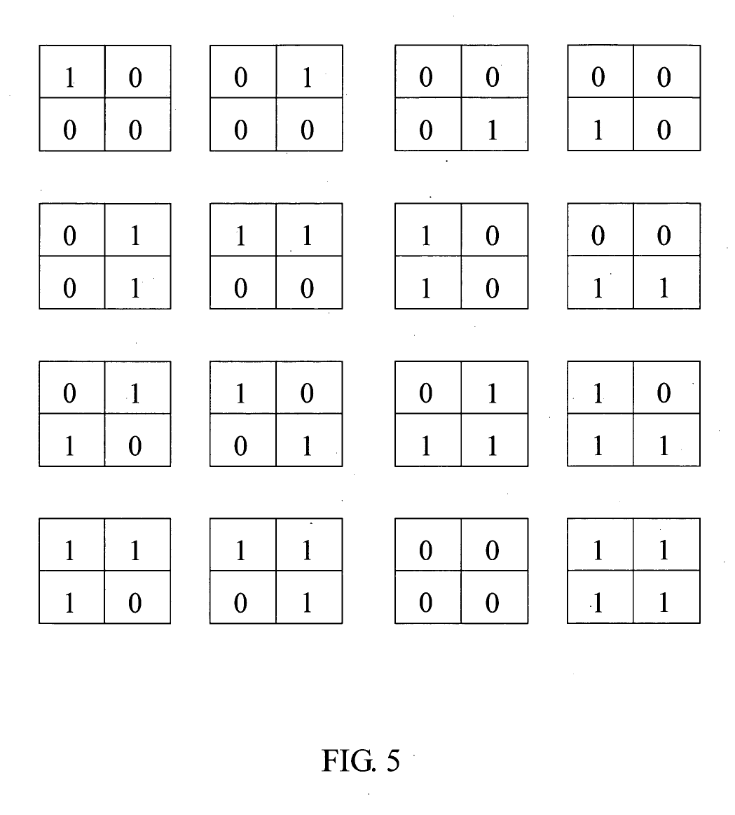

For the first zone, as shows in FIG. 4, each template contains four cells 300, 301, 302, and 303. Each cell may be represented by a value of “1” or “0”. The cell with a value of “1” represents that no hole exists thereon. Namely, the channel region of the transistor is not doped and no resistance exists. The cell with a value of “0” represents that there exists a hole thereon. Since each cell may be represented by “1” or “0”, there are 16 possible distributions (i.e. 2⁴), as illustrated in FIG. 5. That is to, say, each calculation of OPC is contained in one of the 16 possible distributions. Each distribution is defined as a template and there exists 16 templates. For each template, the OPC result is calculated individually. The 16 templates have 16 OPC results and these results are stored. From symmetric viewpoint, the number of template can be reduced greatly by the rotational symmetry of the drawing. For example, in FIG. 5, the templates in the uppermost bank are identical, thus only one template needs to be calculated. By the same way, only five templates are necessary. Since the last template with four cells filled with “1” is unnecessary to calculate, only four templates is needed. Thus, in the present invention, the amount of calculation is greatly reduced.

It must first determine the template the hole belonged. A template matching the environment of the hole is picked out. An OPC result corresponding to the template is directly used in padding the hole. It is unnecessary to calculate the OPC result repeatedly and as a result the amount of calculation is decreased greatly.

If the OPC exposure and padding patterns are not desired, the failure rate of the product will be high. Therefore, other than padding in proper position by OPC, the padding size is also an important factor.

In the following the details for padding a hole of a cell will be described by way of a plurality of embodiments which clearly shows the features of the present invention.

Padding of Lateral Sides of the Hole

As the padding process is used in the lateral sides of a hole, the hole will be affected by its adjacent holes. For example, for the cell X, referring to FIGS. 3 and 6-10, the padding strengths L1, L2, L3 and L4 are determined by adjacent cells at the upper and lower sides (each contains 2*3 cells) and left and right cells (each contains 3*2 cells). Practically, the strength can be simulated so as to generate desired parameters.

By symmetrical property of light, the adjacent 2*3 cells are classified as four classes, i.e. a, b, c and d. According to optics, a>b>c>d and a′>b′>c′>d′. By solving optic equations, it can be found that a=a′=0.4, b=b′=0.2, c=c′=0.18, d=d′=0.01. The padding can be adjusted based on these values.

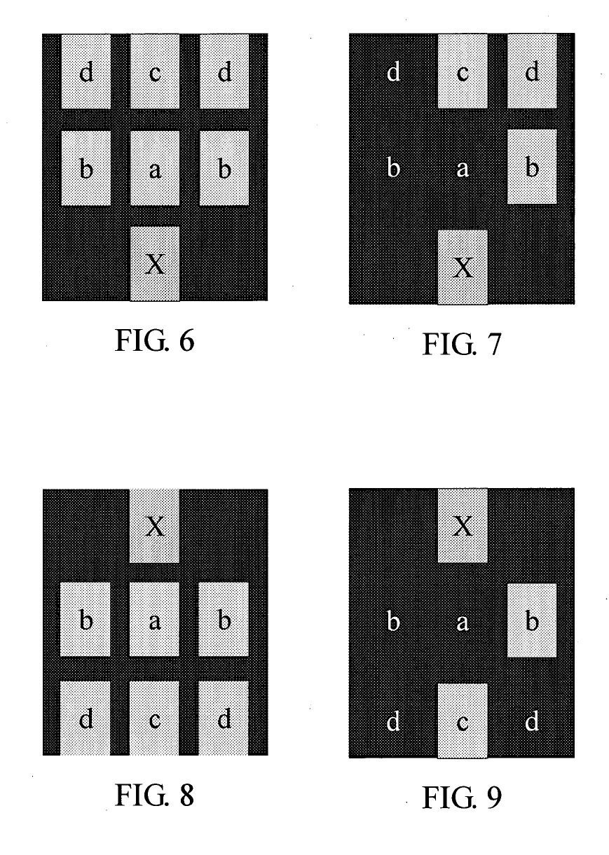

The 2*3 cells above the cell X are used as an example, see FIG. 6. If the six cells are exposed under the emission of the impinging light, the cells will be affected by these cells and OPC padding is used to pad the hole of the cell. The padding strength is:
a+b+b+c+d+d=a+2b+c+2d=1

Here, the padding strength of 1 is the maximum of padding strength. In practical use, the padding value is adjusted according to the size of the cell and optic resistance and is calibrated according to practical measurement. According to the strengths, the granularity of the padding is further classified as four classes, such as [0, 0.25], (0.25, 0.5], (0.5, 0.75], (0.75, 1]. Corresponding to the four sections, respective padding values are acquired. For example, for some products, the padding values are −10 nm, −5 nm, +5 nm and +10 nm, where positive sign represents that the padding is performed at the outer side of the hole and negative sign represents that the padding is performed at the inner side of the hole. For cell X, the padding is performed outward along a direction a to increase the width of exposure area with a size of 10 nm. In another situation, referring to FIG. 7, if only three cells in the 2*3 cells are exposed, the cell X will be affected and OPC optic padding is necessary to be executed. The padding strength is:
b+c+d=0.2+0.18+0.01=0.39

Thereby, the padding is reduced along a direction opposite to a with a size of 5 nm.

The similar way for deriving the padding length can be used to estimate the result of FIG. 7, where only some cells are opened with holes.

In the case of the 2*3 cells below the cell X, referring to FIG. 8, if the six cells are exposed wholly, the cell X will be affected and OPC padding is thus necessary. The padding strength is:
a+b+b+c+d+d=a+2b+c+2d=1

The maximum padding strength is assumed to be 1. The value of padding is adjusted according to the size of the products and the property of optical resistance and is calibrated based on practical measurement result. Based on this strength, the granularity of padding is further classified as four classes, such as [0, 0.25], (0.25, 0.5], (0.5, 0.75], (0.75, 1]. Corresponding to the four sections, respective padding values are acquired. For example, for some products, the padding value is −10 nm, −5 nm, +5 nm, and +10 nm, where positive sign represents that the padding is performed at the outer side of the hole and negative sign represents that the padding is performed at the inner side of the hole. For cell X, the padding is performed outward along a direction a to increase the width of exposure area with a size of 10 nm. In another situation, referring to FIG. 9, if only two cells in the 2*3 cells are exposed, the cell X will be affected and OPC optic padding is necessary to be executed. The padding strength is:
b+c=0.2+0.18=0.38

Thereby, the padding is reduced along a direction opposite to a with a size of 5 nm.

The similar way for deriving the padding length can be used to estimate the result of FIG. 9, where only some cells are opened with holes.

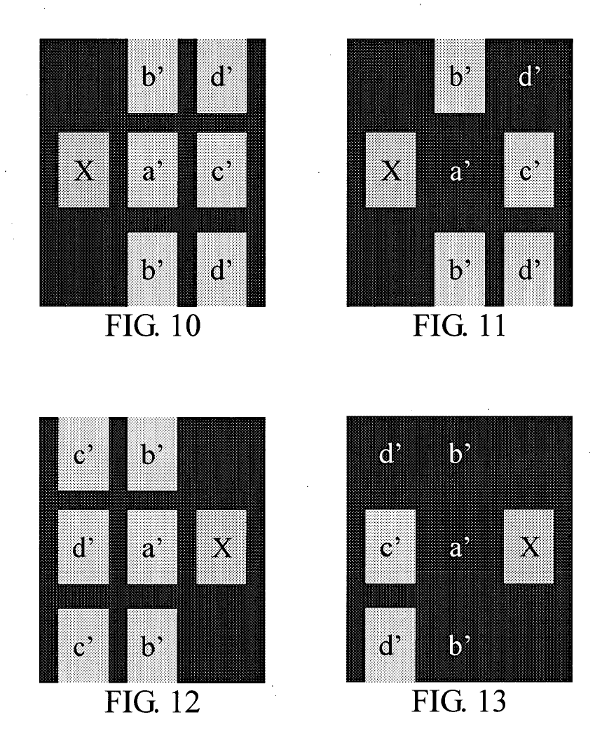

In the case of the 3*2 cells at the right side of the cell X, referring to FIG. 10, the six cells are exposed wholly, the cell X will be affected and OPC padding is thus necessary. The padding strength is:
a′+b′+b′+c′+d′+d′=a′+2b′+c′+2d′=1

Here, the maximum padding strength is assumed to be 1. The value of padding is adjusted according to the size of the products and the property of optical resistance and is calibrated based on practical measurement result. Based on this strength, the granularity of the padding is further classified as four classes, such as [0, 0.25], (0.25, 0.5], (0.5, 0.75], (0.75, 1]. Corresponding to the four sections, respective padding values are acquired. For example, for some products, the padding value is −10 nm, −5 nm, +5 nm, and +10 nm, where positive sign represents that the padding is performed at the outer side of the hole and negative sign represents that the padding is performed at the inner side of the hole. For cell X, the padding is performed outward along a direction a to increase the width of the exposure area with a size of 10 nm. In another situation, referring to FIG. 11, if only four cells in the 3*2 cells are exposed, the cell X will be affected and OPC optic padding is necessary to be executed. The padding strength is:
2b′+c′+d′=2*0.2+0.18+0.01=0.59

The padding is reduced along an outward direction with a size of 5 nm.

The similar way for deriving the padding length can be used to estimate the result of FIG. 11, where only some cells are opened with holes.

In the case of the 3*2 cells at the left side of the cell X, referring to FIG. 12, if the six cells are exposed wholly, the cell X will be affected and OPC padding is necessary. The padding strength is:
a′+b′+b′+c′+d′+d′=a′+2b′+c′+2d′=1

Here, the maximum padding strength is assumed to be 1. The value of padding is adjusted according to the size of the products and the property of optical resistance and is calibrated based on practical measurement result. Based on this strength, the granularity of the padding is further classified as four classes, such as [0, 0.25], (0.25, 0.5], (0.5, 0.75], (0.75, 1]. Corresponding to the four sections, respective padding values are acquired. For example, for some products, the padding value is −10 nm, −5 nm, +5 nm, and +10 nm, where positive sign represents that the padding is performed at the outer side of the hole and negative sign represents that the padding is performed at the inner side of the hole. For cell X, the padding is performed outward along a direction a to increase the width of exposure area with a size of 10 nm. In another situation, referring to FIG. 13, if only two cells in the 3*2 cells are exposed, the cell X will be affected and OPC optic padding is necessary to be executed. The padding strength is:
c′+d′=0.18+0.01=0.19

The padding is reduced along an inward direction with a size of 10 nm.

The similar way for deriving the padding length can be used to estimate the result of FIG. 13, where only some cells are opened with holes.

Padding of Corners

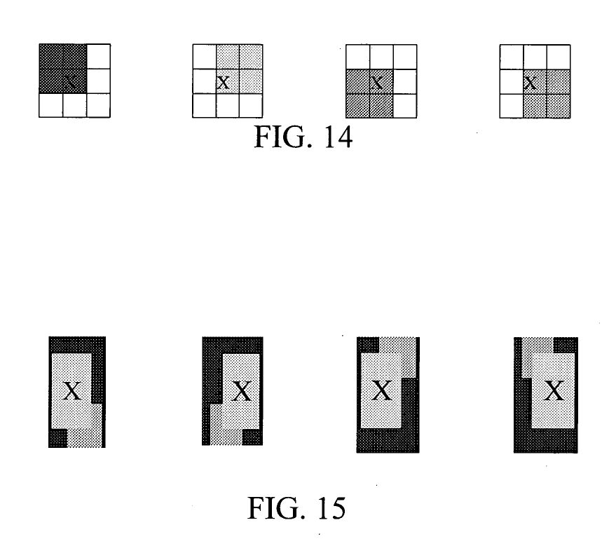

The padding of corners will be described hereinafter. The diffraction of the hole in this case is mainly affected the adjacent holes to be exposed by light. For example, the padding strength of a hole in a cell is determined by the adjacent exposure area (containing 2*2 exposure area). With reference to FIG. 14, the adjacent 2*2 cells will affect the cell X. For each area, the shape of padding and strength is determined based on the type of the hole. In this case, the corner to be padded is padded with an L shape pad which may be turned to different orientation, as shown in FIG. 15.

Assume Sₓ₀, S_{y0} represents the values of preset padding values, which are adjustable based on size and resistance of a product. The strength of the padding strength is classified as three classes:
(Sₓ₀, Sₓ₁, Sₓ₂)=(Sₓ₀,Sₓ₀+rₓ₁, Sₓ₀+rₓ₂)=(50, 55, 60)
(S_{y0}, S_{y1}, S_{y2})=(Sₓ₀,Sₓ₀+r_{y1}, Sₓ₀+r_{y2})=(50, 55, 60)
where rₓ₁, rₓ₂ are x-bias, which are the padding strength increment in X axis for different exposure pattern in 2*2 cells, and r_{y1}, r_{y2} are y-bias, which are the padding strength increment in Y axis for different exposure pattern in 2*2 cells.

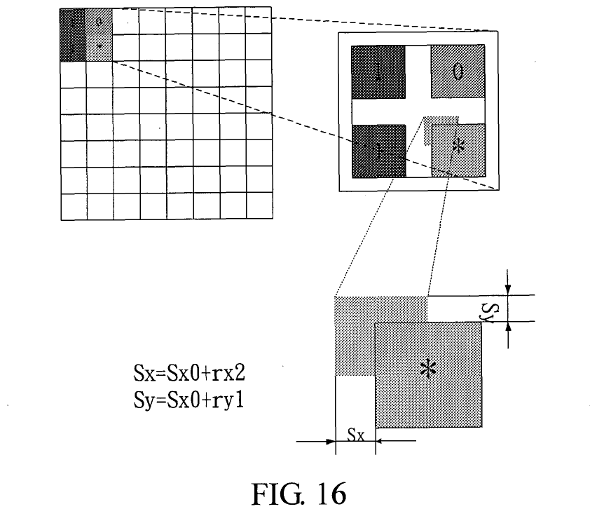

Sₓᵢ,i=0, 1, 2, S_{yj},j=0, 1, 2 are total padding strength x-bias and y-bias. The definition may be referred to the schematic view of FIG. 16.

The padding strength is based on experiments which are used to calibrate the practical measurement. In this case, rₓ₁=r_{y1}=5, rₓ₂=r_{y2}=10. Different padding shape and strength are needed for different exposure shapes. The corner padding method of the present invention is over the current used commercial OPC software, in that, only cells in the vertical and horizontal directions are used to determine the padding. In the padding method of the present invention, the cells in the orthogonal directions are used to pad the padding area of a hole. The padding value is more precise and more useful. The padding ways and padding positions for different cell distributions in a mask are listed in Tables 1 to 4.

OPC Padding System

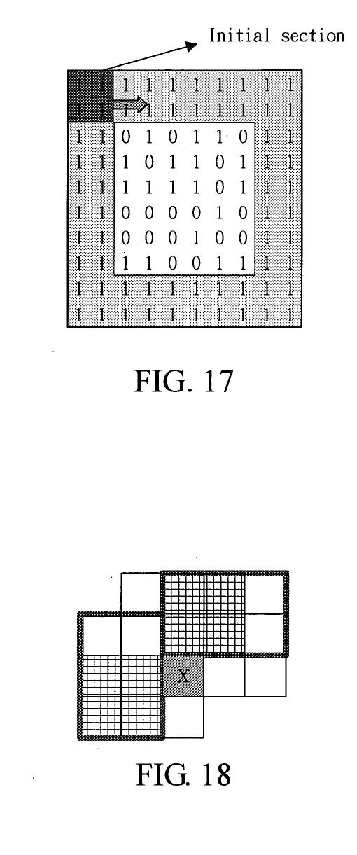

Other than built-in digitalized padding rule in the OPC optic padding system, the considered rows and columns affected the diffraction of a hole can be expanded into two banks. In above-mentioned lateral side compensation and corner edge compensation, the cells to be considered to have effects to the diffraction of a hole are modulized as basic templates containing 3*3, 2*3 and 2*2 cells. The digital array of a mask of a ROM code can be expanded outward through two rows or columns so as to be formed as an array, as shown in FIG. 17. For a very large integrated circuit, the method of the present invention can be used to decompose a large exposure area into a plurality of smaller area so as to operate with a higher speed without the result be affected.

In the following, the padding strengths with respect to different padding patterns in different padding positions are described with reference to Tables 1, 2 and 3.

If a practical exposure pattern is

$$[ \begin{matrix}A & B \\ C & D\end{matrix} ]$$

in the following tables, the pattern is represented as (A, B, C, D), where A, B, C, D are binary variables, which may be 0 or 1. If it is equal to zero, it is a hole with light transmission property. Otherwise, if it is 1, the area is not transparent. “*” represents the cell to be padded, which in this embodiment has a value of zero.

In exposure patterns and padding positions in the leftmost positions of Tables 1, 2, 3 and 4 are only examples.

The padding size is adjusted based on the size and the resistance of the product:
(Sₓ₀, Sₓ₁, Sₓ₂)=(Sₓ₀, Sₓ₀+rₓ₁, Sₓ₀+rₓ₂)=(50, 55, 60)
and
(S_{y0}, S_{y1}, S_{y2})=(Sₓ₀, Sₓ₀+r_{y1}, Sₓ₀+r_{y2})=(50, 55, 60)

The area considered in lateral side padding and corner padding can be expanded as desired, as can be seen in FIG. 18. The shaded area of 2*2 cells are extended type of above the method.

TABLE 1

| Exposure | | |
|---|---|---|
| pattern and padding position | Exposure pattern | Padding strength |
| 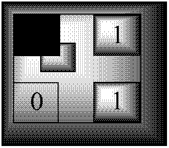 | *000 *001 *010 *011 *100 *101 *110 *111 | Sₓ₀,S_{y0 S}ₓ₁,S_{y1 S}ₓ₀,S_{y1 S}ₓ₁,S_{y2 S}ₓ₁,S_{y0 S}ₓ₂,S_{y1 S}ₓ₁,S_{y1 S}ₓ₂,S_{y2} |

The cell to be padded is at the left upper side, where only * is equal to 0, padding is performed.

TABLE 2

| Exposure | | |
|---|---|---|
| pattern and padding position | Exposure pattern | Padding strength |
| 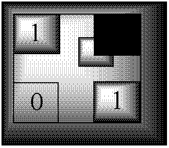 | 0*00 0*01 0*10 0*11 1*00 1*01 1*10 1*11 | Sₓ₀,S_{y0 S}ₓ₀,S_{y1 S}ₓ₁,S_{y1 S}ₓ₁,S_{y2 S}ₓ₁,S_{y0 S}ₓ₁,S_{y1 S}ₓ₂,S_{y1 S}ₓ₂,S_{y2} |

The cell to be padded is at the left lower side, where only * is equal to 0, padding is performed.

TABLE 3

| Exposure | | |
|---|---|---|
| pattern and padding position | Exposure pattern | Padding strength |
| 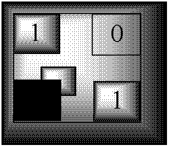 | 00*0 00*1 01*0 01*1 10*0 10*1 11*0 11*1 | Sₓ₀,S_{y0 S}ₓ₁,S_{y0 S}ₓ₀,S_{y1 S}ₓ₁,S_{y1 S}ₓ₁,S_{y1 S}ₓ₂,S_{y1 S}ₓ₀,S_{y2 S}ₓ₂,S_{y2} |

The cell to be padded is at the right lower side, where only * is equal to 0, padding is performed.

TABLE 4

| Exposure | | |
|---|---|---|
| pattern and padding position | Exposure pattern | Padding strength |
| 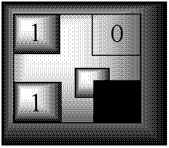 | 000* 001* 010* 011* 100* 101* 110* 111* | Sₓ₀,S_{y0 S}ₓ₁,S_{y0 S}ₓ₀,S_{y1 S}ₓ₁,S_{y1 S}ₓ₁,S_{y1 S}ₓ₂,S_{y1 S}ₓ₀,S_{y2 S}ₓ₂,S_{y2} |

The cell to be padded is at the right lower side, where only * is equal to 0, padding is performed.
Experimental Result

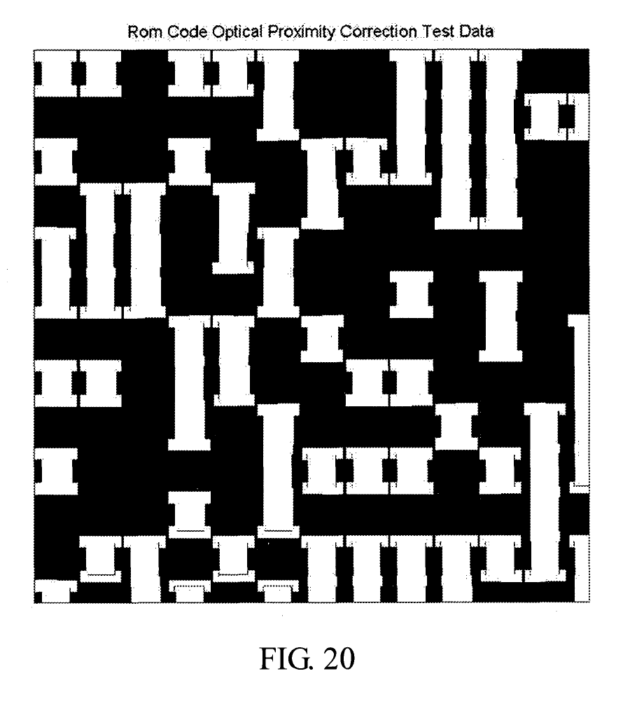

In the present invention, a modulized OPC padding method has been disclosed. The method of the present invention is applied to an OPC padding system. FIGS. 19A and 19B show patterns before padding and after padding, respectively, wherein each pattern contains 50*50 cells and each cell is designated with a value “0” or “1”. FIG. 19B shows the pattern processed by the modulized OPC padding method of the present invention. FIG. 20 is a partial enlarged view of the pattern at the left upper side of FIG. 19B, which pattern is processed by the method of the present invention.

Although the present invention has been described with reference to the preferred embodiments, it will be understood that the invention is not limited to the details described thereof Various substitutions and modifications have been suggested in the foregoing description, and others will occur to those of ordinary skill in the art. Therefore, all such substitutions and modifications are intended to be embraced within the scope of the invention as defined in the appended claims.

1. A template padding method for padding edges of at least one hole on a semiconductor mask, the mask being provided on a contact layer formed on a wafer for forming elements, light being impinged into the hole to develop an image of the hole on the contact layer, thereby, the wafer being doped to form semiconductor elements, the mask being divided into a plurality of cells and at least one cell having a hole, the method comprising the steps of:
determining a zone enclosing the hole on the mask, the zone containing a plurality of cells;
selecting a template adjacent one selected edge to be padded, the template containing the hole and parts of cells in the zone;
determining the padded length based on a diffraction result of the hole and cells on the template; and
padding all edges of the at least one hole.

2. The method of claim 1, wherein the zone is a collection of at least one bank of cells around the hole, each bank is formed by a plurality of cells formed as a closed loop.

3. The method of claim 2, wherein the template is a cell array formed by a plurality of adjacent banks with each bank having the same number of cells.

4. The method of claim 3, wherein the diffraction of the template for the hole is calculated and stored as a database.

5. The method of claim 4, wherein the diffraction of the template is determined by OPC.

6. The method of claim 5, wherein the diffraction of the template is determined by rule OPC.

7. The method of claim 6, wherein the diffraction of the template is determined by model OPC.

8. The method of claim 1, wherein the edges are lateral sides of the hole to be padded.

9. The method of claim 8, wherein the template has a plurality of cells aside the hole to be padded so that the hole to be padded is protruded from a pattern containing the cells in the template.

10. The method of claim 1, wherein the edges are corners of the hole to be padded.

11. The method of claim 10, wherein the template has a plurality of cells enclosing two outer edges of the corner.

12. The method of claim 2, wherein the zone is selected based on a feature size of the hole to be padded and a wavelength of light to be impinged into the hole for developing.

13. The method of claim 1, wherein the semiconductor element is a ROM.

14. The method of claim 13, wherein the cell is a transistor containing a source, a drain and a channel.

15. The method of claim 14, wherein the channel is doped to form a resistor.

16. The method of claim 1, wherein the cells are arranged as an array.

17. A method for determining a padding length of a padded hole in a template, the template containing a cell array and being a sub-set of a zone on a mask enclosing the padded hole, the cell array being formed by a plurality of adjacent banks each containing a predetermined number of cells, the method comprising the steps of:
(b1) determining a geometrical relation of a selected cell to the at least one hole to be padded for a cell having a hole;
(b2) determining a padding value according to diffraction of the selected cell and the hole;
(b3) determining cells in the template having the same geometrical relation to the padded hole as that in step (b1), the padding value being equal to that acquired from (b2);
(b4) determining all the padding values for each cell in the template;
(b5) adding all of the padding values of each cells in the template; and
(b6) determining a padding length according to the padding values for expanding an edge of the padded hole, wherein the edge of the hole to be expanded is one of edges of the hole nearest to the template.

18. The method of claim 17, wherein the edge of the hole to be expanded is one of the edges nearest to a geometrical center of the template.

19. The method of claim 17, wherein the padding value is determined by experiments.

20. The method of claim 17, wherein the padding value is determined by calculation of diffraction of the padded hole to the selected cell.

21. The method of claim 17, wherein the padding value is determined by OPC method.

22. The method of claim 17, wherein the padding value is determined by rule OPC.

23. The method of claim 17, wherein the padding value is determined by model OPC.

24. The method of claim 17, wherein the step of determining the padding length based on the padding value is performed by experiments.

25. The method of claim 17, wherein the step of determining the padding length based on the padding value is performed by calculation of diffraction.

26. The method of claim 17, wherein the step of determining the padding length based on the padding value is performed by OPC method.

27. The method of claim 17, wherein the step of determining the padding length based on the padding value is performed by rule OPC method.

28. The method of claim 17, wherein the step of determining the padding length based on the padding value is performed by model OPC method.

29. The method of claim 18, wherein the padding values for each template is stored in a database.
